(19) United States
(12) Patent Application Publication
(10) Pub. No.: US 2024/0222115 A1
(43) Pub. Date: Jul. 4, 2024

(54) METHOD AND SYSTEM FOR DEPOSITING BORON CARBON NITRIDE

(71) Applicant: ASM IP Holding B.V., Almere (NL)

(72) Inventor: Antti Niskanen, Helsinki (FI)

(21) Appl. No.: 18/396,857

(22) Filed: Dec. 27, 2023

Related U.S. Application Data
(60) Provisional application No. 63/436,125, filed on Dec. 30, 2022.

(51) Int. Cl. H01L 21/02; C23C 16/34; C23C 16/455; H01J 37/32

(52) U.S. Cl. CPC H01L 21/0262; C23C 16/342; C23C 16/347; C23C 16/45542; C23C 16/45544; C23C 16/45553; H01J 37/32082; H01J 37/32449; H01L 21/02521; H01J 2237/327; H01J 2237/3321

(57) ABSTRACT

Methods for forming a layer comprising boron carbon nitride on a substrate by a plasma enhanced atomic layer deposition (PEALD) process are provided. The methods comprise executing a plurality of deposition cycles. A deposition cycle comprises a boron precursor pulse that comprises exposing the substrate to a boron precursor and a silicon-containing precursor pulse that comprises exposing the substrate to a silicon-containing precursor. A deposition cycle further comprises a plasma pulse that comprises exposing the substrate to a plasma treatment. The plasma treatment comprises generating a plasma.

### CROSS-REFERENCE TO RELATED APPLICATIONS

This application claims priority to and the benefit of U.S. Provisional Application No. 63/436,125, filed Dec. 30, 2022, the entirety of which is incorporated by reference herein.

### FIELD OF INVENTION

The present disclosure generally relates to methods to the field of semiconductor processing methods and systems. In particular, methods and systems that can be used for depositing boron carbon nitride (BCN) layer by a cyclical deposition process.

### BACKGROUND OF THE DISCLOSURE

The down-scaling of semiconductor devices has resulted in improvements in the speed and density of integrated circuits. However, the miniaturization of devices is limited by increased resistance of interconnects and capacitance delay. To overcome this, interconnect materials having low relative dielectric constants (κ-values), that have low wet etch rate ratios (WERR) relative to other commonly-used materials, that serve as metal diffusion barriers, and that are thermally, chemically, and mechanically stable, are desirable. This has been difficult to obtain with materials such as low-κ SiCO that generally exhibit poor thermo-mechanical properties.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of depositing a layer comprising boron, carbon and nitrogen, to structures and devices formed using such methods, and to apparatus for performing the methods and/or for forming the structures and/or devices. The layers may be used for variety of applications, including etch stop layers, low-k layers, back-end-of-line dielectrics, capping layers, spacers, and others.

Described herein is a method for forming a layer comprising boron, carbon and nitrogen on a substrate. The method comprises: providing a substrate into a reaction chamber; and executing a plurality of deposition cycles. A deposition cycle comprises: providing a boron precursor in vapor phase in the reaction chamber; providing a silicon-containing precursor in vapor phase in the reaction chamber; providing a plasma gas in the reaction chamber; and generating a plasma in the plasma gas.

Further described herein is a semiconductor processing apparatus. The apparatus comprises a reaction chamber, a heater, a plasma module, a plasma gas source, a boron precursor source, a silicon-containing precursor source, and a controller. The reaction chamber comprises a substrate support for supporting a substrate.

The heater is constructed and arranged to heat the substrate in the reaction chamber. The plasma module comprises a radio frequency power source that is constructed and arranged to generate a plasma. The plasma gas source is in fluid communication with the plasma module. The boron precursor source is in fluid connection with the reaction chamber via one or more precursor valves. The silicon-containing precursor source is in fluid connection with the reaction chamber via one or more precursor valves. The controller is configured for causing the semiconductor processing apparatus to perform a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 shows a schematic representation of an embodiment of a system (100) as described herein.

FIG. 2 shows a schematic representation of another embodiment of a system (200) as described herein.

FIG. 3 shows a schematic representation of a plasma-enhanced atomic layer deposition (PEALD) apparatus suitable for depositing a structure and/or for performing a method in accordance with at least one embodiment of the present disclosure.

FIG. 4 shows a schematic representation of an embodiment of a method as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a layer may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. Exemplary gasses can include precursors and reactants.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said wording. When the term “consisting” is used referring to a chemical compound or substance, it indicates that the chemical compound only contains the components which are listed.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

As used herein, a “structure” can be or include a substrate as described herein. Structures can include one or more layers overlying the substrate, such as one or more layers formed according to a method as described herein. Device portions and interconnects can be or include structures.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential exposure of a substrate to precursors (and/or reactants) into a reaction chamber, and exposure of a substrate to plasma generated species to deposit a layer over the substrate and includes processing techniques such as plasma-enhanced atomic layer deposition (PEALD).

The term “plasma-enhanced atomic layer deposition” can refer to a deposition process in which deposition cycles, typically a plurality of consecutive deposition cycles, are conducted in a process chamber.

Generally, for a PEALD processes, during each cycle, a precursor is introduced to a reaction chamber and is chemisorbed to a deposition surface (e.g., a substrate surface that can include a previously deposited material from a previous PEALD cycle or other material) and forming about a monolayer or sub-monolayer of material that does not readily react with additional precursor (i.e., a self-limiting reaction). Thereafter, the substrate is exposed to a plasma-generated species which can be generated using any plasma, such as a direct, indirect, or remote plasma. Plasmas can be generated capacitively, inductively, using microwave radiation, or through other means. The plasma-generated species converts the chemisorbed precursor to the desired material on the deposition surface. Purging steps can be utilized during one or more cycles, e.g., after each step or pulse of each cycle, to remove any excess precursor from the process chamber and/or remove any excess plasma-generated species and/or reaction byproducts from the reaction chamber.

As used herein, the term “purge” may refer to a procedure in which a purge gas is provided to a reaction chamber in between a precursor pulse and a plasma pulse. It shall be understood that during a purge, the substrate is not exposed to plasma-generated species. For example, when a direct plasma is used, the plasma can be turned off during a purge. For example, a purge, e.g. using a purge gas such as nitrogen or a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

Described herein is a method for forming a layer comprising boron carbon nitride on a substrate. The method comprises positioning a substrate on a substrate support in a reaction chamber. Then, the method comprises executing a plurality of deposition cycles. A deposition cycle comprises providing a boron precursor into the reaction chamber in vapor phase, providing a silicon-containing precursor into the reaction chamber in vapor phase, providing a plasma gas into the reaction chamber and generating a plasma in the plasma gas. Thus, a layer comprising boron, carbon and nitrogen is formed on the substrate.

The precursors and plasma are provided into the reaction chamber in pulses. It shall be understood that the boron precursor pulses, silicon-containing precursor pulses and the plasma pulses are executed sequentially, i.e. one after the other, in a non-overlapping fashion. Optionally, the purges are carried out in between the boron precursor pulses, silicon-containing precursor pulses and the plasma pulses.

In some embodiments, the silicon-containing precursor has a structure according to general formula i)

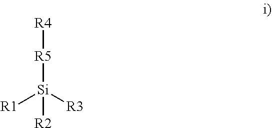

In some embodiments, R1, R2, R3 may be selected from the group consisting of hydrogen and hydrocarbyl group. Suitable hydrocarbyls include alkyls, aryls, and alkenyls. In some embodiments, R1, R2, R3 comprises methyl. It is to be understood that R1, R2, R3 may all be the similar or they may all be mutually different. In some embodiments, R5 may be carbon or nitrogen. In some embodiments R4 comprises at least one carbon-containing ligand. In some embodiments, R4 comprises at least one hydrocarbyl group. Suitably hydrocarbyls include alkyls, aryls and alkenyls. In some further embodiments, R4 comprises a heterocyclic ligand. In some further embodiments, R4 comprises N—C—N heterocycles. In some embodiments, R4 comprises a heterocycle comprising other atoms than only carbon.

In some embodiments, the silicon-containing precursor does not comprise a ligand comprising halogen or oxygen atoms.

In some embodiments, the silicon-containing precursor comprises amine ligand or amine derivative ligand, such as amidinate ligand. In some embodiments, the silicon-containing precursor comprises di(sec-butylamino)silane.

In some embodiments, the boron precursor comprises a boron halide. In some embodiments, the boron precursor comprises a boron trihalide. In some embodiments, the boron halide comprises boron bromide (BBr₃).

In some embodiments, the plasma is a direct capacitively coupled plasma and a plasma pulse comprises a plasma on sub-pulse and a plasma off sub-pulse. In some embodiments, the plasma is an inductively coupled plasma an a plasma pulse comprises a plasma on sub-pulse and a plasma off sub-pulse. During the plasma on sub pulse, the plasma is generated, and during the plasma off sub-pulse, plasma generation is stopped.

A plasma pulse can suitably comprise exposing the substrate to a plasma treatment. The plasma treatment comprises generating a plasma. The plasma can be one of a remote plasma, an indirect plasma, and a direct plasma.

Plasmas can be suitably generated by means of a plasma gas. Plasma gasses are gasses, vapors, gas mixtures, or a combination thereof that are provided to a space in which a plasma is generated. Suitable plasma gasses include H₂, N₂, NH₃ and noble gasses such as He and Ar.

In some embodiments, the plasma is a direct capacitively coupled plasma generated between a showerhead injector and the substrate. In some embodiments, a direct capacitively coupled plasma can employ a plasma power from at least 175 W to at most 400 W, such as 200 W to 350 W, for example about 350 W.

Thus, a boron carbon nitride material can be formed that has a thickness of e.g. 0.1 to 1.0 Å/cycle.

In some embodiments, the plasma is an Ar/H₂ plasma. In other words, and in some embodiments, the plasma employs a plasma gas that substantially consists of Ar and H₂. In some embodiments, the plasma is an Ar/N₂/H₂ plasma. In other words, in some embodiments, the plasma employs a plasma gas that substantially consists of Ar, N₂ and H₂. In some embodiments, the plasma is an Ar plasma. In other words, and in some embodiments, the plasma employs a plasma gas that substantially consists of Ar. In some embodiments, the plasma is a He plasma. In other words, and in some embodiments, the plasma employs a plasma gas that substantially consists of He. In some embodiments, the plasma is an N₂/H₂ plasma. In other words, and in some embodiments, the plasma employs a plasma gas that substantially consists of N₂ and H₂. In some embodiments, the plasma is an NH₃ plasma. In other words, and in some embodiments, the plasma employs a plasma gas that substantially consists of NH₃. In some embodiments, the plasma is a He/H₂ plasma. In other words, and in some embodiments, the plasma employs a plasma gas that substantially consists of He and H₂.

In some embodiments, the substrate is maintained at a temperature of at least 200° C. to at most 600° ° C., or at a temperature of at least 200° ° C. to at most 500° ° C., or at a temperature of around 250° C. during the deposition cycles.

In some embodiments, reaction chamber is maintained at a pressure from 1 Pa to at most 150 Pa, or at a pressure from at least 100 Pa to at most 2000 Pa, or at a pressure from at least 500 Pa to at most 1000 Pa.

The layer comprising boron carbon nitride having a desired thickness can be formed on the substrate by executing a suitable number of deposition cycles. The total number of deposition cycles comprised in a method as described herein depends, inter alia, on the total layer thickness that is desired. In some embodiments, the method comprises from at least 2 deposition cycles to at most 5 deposition cycles, or from at least 5 deposition cycles to at most 10 deposition cycles, or from at least 10 deposition cycles to at most 20 deposition cycles, or from at least 20 deposition cycles to at most 50 deposition cycles, or from at least 50 deposition cycles to at most 100 deposition cycles, or from at least 100 deposition cycles to at most 200 deposition cycles, or from at least 200 deposition cycles to at most 500 deposition cycles, or from at least 500 deposition cycles to at most 1000 deposition cycles, or from at least 1000 deposition cycles to at most 2000 deposition cycles, or from at least 2000 deposition cycles to at most 5000 deposition cycles, or from at least 5000 deposition cycles to at most 10000 deposition cycles. For example, the layer comprising boron carbon nitride can have a thickness of at least 1 nm to at most 20 nm, such as a thickness of 2 nm, 5 nm, 10 nm, and 15 nm.

Further described herein is a semiconductor processing apparatus. The semiconductor processing apparatus comprises a reaction chamber. The reaction chamber comprises a substrate support for supporting a substrate.

The system further comprises a heater. The heater is constructed and arranged to heat the substrate in the reaction chamber.

The system further comprises a plasma module. The plasma module comprises a radio frequency power source that is constructed and arranged to generate a plasma. In some embodiments, the plasma module is arranged in a remote plasma configuration in which the plasma can be generated outside of the reaction chamber, and in which plasma-generated active species can be directed to the substrate. In some embodiments, the plasma module is arranged in a direct plasma configuration in which the plasma is generated in the reaction chamber and in which the plasma is not physically separated from the substrate.

The system further comprises a suitable amount of sources. For example, the system can comprise a plasma gas source in fluid connection with the plasma module, a boron precursor source in fluid connection with the reaction chamber via one or more precursor valves and a silicon-containing precursor source in fluid connection with the reaction chamber via one or more precursor valves. In one embodiment, the plasma module and/or the plasma gas source have a valve, that gases can be removed in between the precursor providing steps with a pump.

The system further comprises a controller. The controller is configured for causing the semiconductor processing apparatus to perform a method as described herein.

Optionally, the system is configured for providing the boron precursor and the silicon-containing precursor to the reaction chamber by means of a carrier gas. Suitable carrier gasses include noble gasses. In other words, in some embodiments, the semiconductor processing system comprises a gas injection system comprising a precursor delivery system that employs a carrier gas for carrying the precursor to one or more reaction chambers.

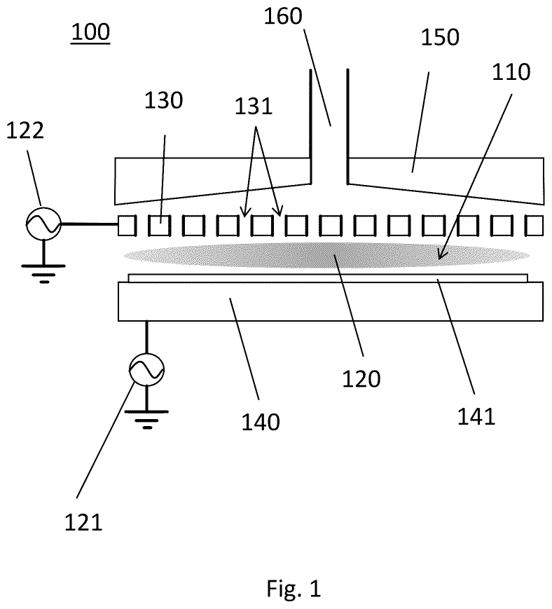

FIG. 1 shows a schematic representation of an embodiment of a system (100) as described herein. The system (100) comprises a reaction chamber (110) in which a plasma (120) is generated. In particular, the plasma (120) is generated between a showerhead injector (130) and a substrate support (140). This is a direct plasma configuration employing a capacitively coupled plasma.

In the configuration shown, the system (100) comprises two alternating current (AC) power sources: a high frequency power source (121) and a low frequency power source (122). In the configuration shown, the high frequency power source (121) supplies radio frequency (RF) power to the showerhead injector, and the low frequency power source (122) supplies an alternating current signal to the substrate support (140). The radio frequency power can be provided, for example, at a frequency of 13.56 MHz or higher, e.g. at a frequency of at least 100 kHz to at most 50 MHz, or at a frequency of at least 50 MHz to at most 100 MHz, or at a frequency of at least 100 MHz to at most 200 MHz, or at a frequency of at least 200 MHz to at most 500 MHz, or at a frequency of at least 500 MHz to at most 1000 MHz, or at a frequency of at least 1000 MHz to at most 2000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz.

Process gas comprising precursor, reactant, or both, is provided through a gas line (160) to a conical gas distributor (150). The process gas then passes through holes (131) in the showerhead injector (130) to the reaction chamber (110).

Whereas the high frequency power source (121) is shown as being electrically connected to the showerhead injector, and the low frequency power source (122) is shown as being electrically connected to the substrate support (140), other configurations are possible as well. For example, in some embodiments (not shown), both the high frequency power source and the low frequency power source can be electrically connected to the showerhead injector; or both the high frequency power source and the low frequency power source can be electrically connected to the substrate support; or the high frequency power source can be electrically connected to the substrate support, and the low frequency power source can be electrically connected to the showerhead injector.

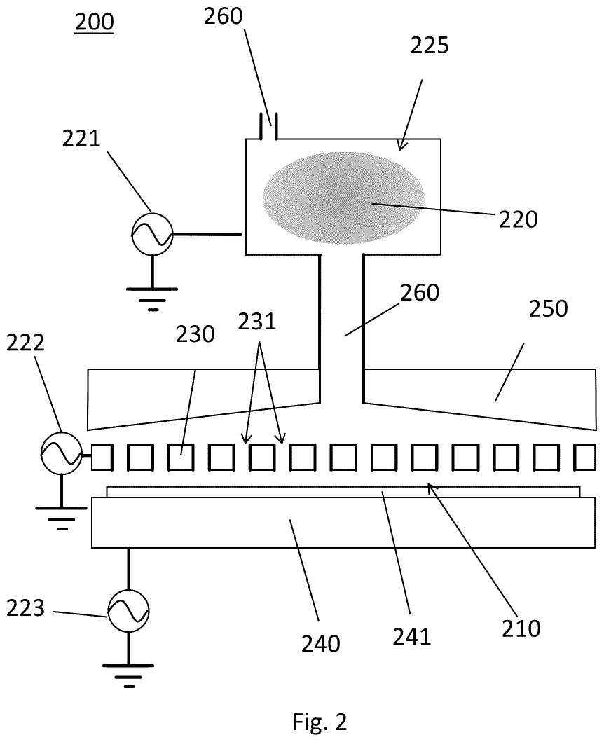

FIG. 2 shows a schematic representation of another embodiment of a system (200) as described herein. The configuration of FIG. 2 can be described as a remote plasma system. The system (200) comprises a reaction chamber (210) which is operationally connected to a remote plasma source (225) in which a plasma (220) is generated. Any sort of plasma source can be used as a remote plasma source (225), for example an inductively coupled plasma, a capacitively coupled plasma, or a microwave plasma.

In particular, active species are provided from the plasma source (225) to the reaction chamber (210) via an active species duct (260), to a conical distributor (250), through holes (231) in a shower plate injector (230), to the reaction chamber (210). Thus, active species can be provided to the reaction chamber in a uniform way.

In the configuration shown, the system (200) comprises three alternating current (AC) power sources: a high frequency power source (221) and two low frequency power sources (222,223): a first low frequency power source (222) and a second low frequency power source (223). In the configuration shown, the high frequency power source (221) supplies radio frequency (RF) power to the plasma generation space ceiling, the first low frequency power source (222) supplies an alternating current signal to the showerhead injector (230), and the second low frequency power source (223) supplies an alternating current signal to the substrate support (240). A substrate (241) is provided on the substrate support (240). The radio frequency power can be provided, for example, at a frequency of 13.56 MHz or higher. The low frequency alternating current signal of the first and second low frequency power sources (222,223) can be provided, for example, at a frequency of 2 MHz or lower.

In some embodiments (not shown), an additional high frequency power source can be electrically connected to the substrate support. Thus, a direct plasma can be generated in the reaction chamber.

Process gas comprising precursor, reactant, or both, is provided to the plasma source (225) by means of a gas line (260). Active species such as ions and radicals generated by the plasma (225) from the process gas are guided to the reaction chamber (210).

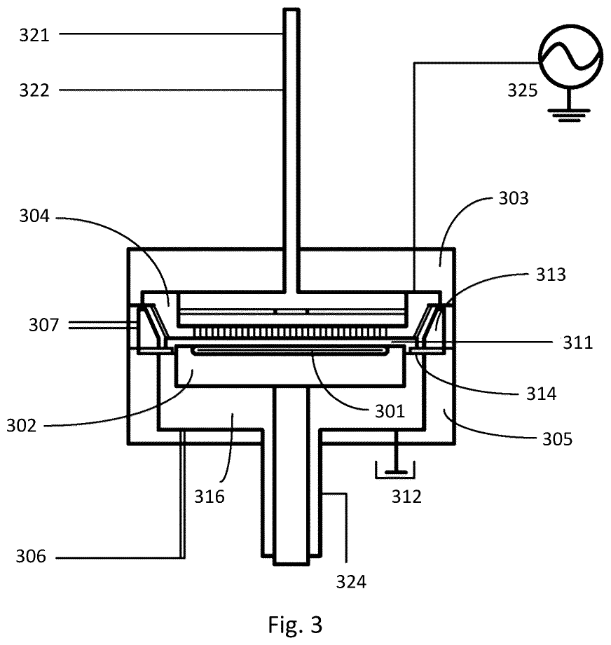

The presently provided methods may be executed in any suitable apparatus, including in an embodiment of a semiconductor processing system as shown in FIG. 3. FIG. 3 is a schematic view of a plasma-enhanced atomic layer deposition (PEALD) apparatus, usable in some embodiments of the present invention. In this figure, by providing a pair of electrically conductive flat-plate electrodes (302,304) in parallel and facing each other in the interior (311) (reaction zone) of a reaction chamber (303), applying RF power (e.g. at 13.56 MHz and/or 27 MHz) from a power source (325) to one side, and electrically grounding the other side (312), a plasma can be generated between the electrodes. Of course, there is no need for the semiconductor processing apparatus to generate a plasma during the steps when a precursor is provided to the reaction chamber, or during purges between subsequent processing steps, and no RF power need be applied to any one of the electrodes during those steps or purges. A temperature regulator may be provided in a lower stage (302), i.e. the lower electrode. A substrate (301) is placed thereon and its temperature is kept constant at a given temperature. The upper electrode (304) can serve as a shower plate as well, and various gasses such as a plasma gas, a reactant gas and/or a dilution gas, if any, as well as a precursor gas can be introduced into the reaction chamber (303) through a gas line (321) and a gas line (322), respectively, and through the shower plate (304). Additionally, in the reaction chamber (303), a circular duct (313) with an exhaust line (317) is provided, through which the gas in the interior (311) of the reaction chamber (303) is exhausted. Additionally, a transfer chamber (305) is disposed below the reaction chamber (303) and is provided with a gas seal line (324) to introduce seal gas into the interior (311) of the reaction chamber (303) via the interior (316) of the transfer chamber (305) wherein a separation plate (314) for separating the reaction zone and the transfer zone is provided.

Note that a gate valve through which a wafer may be transferred into or from the transfer chamber (305) is omitted from this figure. The transfer chamber is also provided with an exhaust line (306).

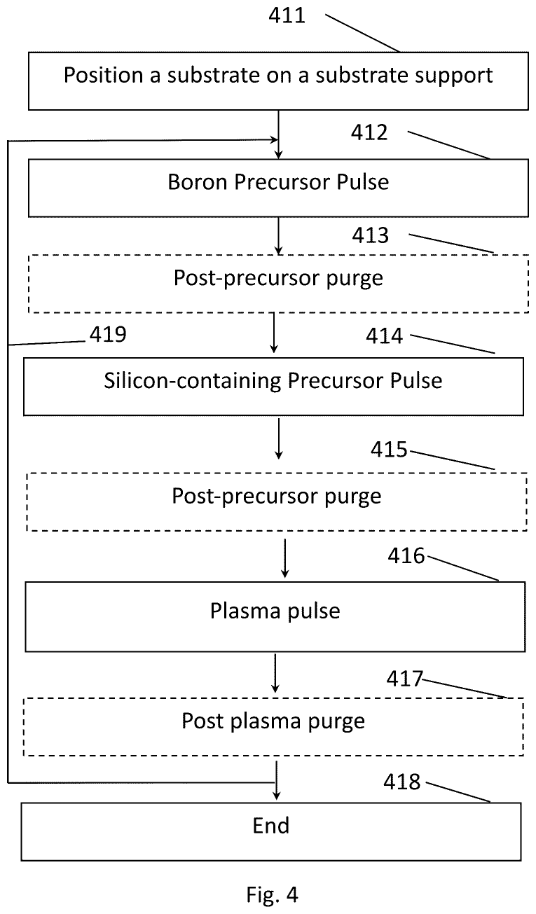

FIG. 4 shows a schematic representation of an embodiment of a method as described herein. The method comprises a step (411) of positioning a substrate on a substrate support. Then, the method comprises sequentially executing a plurality of deposition cycles (419). A deposition cycle (419) comprises a boron precursor pulse (412), a silicon-containing precursor pulse (414) and a plasma pulse (416). The boron precursor pulse (412) comprises exposing the substrate to a boron precursor (412). In one embodiment the pulse time may be between 0.01 to 2 seconds, or between 0.3 to 1 seconds. The silicon precursor pulse (414) comprises exposing the substrate to a silicon precursor (414). In one embodiment the pulse time may be between 0.01 to 2 seconds, or between 0.3 to 1 seconds. The plasma pulse (416) comprises exposing the substrate to plasma-generated active species. In one embodiment the pulse time may be between 0 to 10 seconds, or between 1 to 5 seconds. The active species can be generated using a remote or direct plasma configuration as explained elsewhere herein. It shall be understood that a boron precursor pulse (412), a silicon-containing precursor pulse (414) and a plasma pulse (416) do not overlap, or do not substantially overlap. In other words, the boron precursor pulse (412), the silicon-containing precursor pulse (414) and the plasma pulse (416) are carried out sequentially. In some embodiments, the precursor pulses (412, 414) and the plasma pulses (416) are separated by purges (413, 415, 417). In other words, in some embodiments, the boron precursor pulse (412) is followed by a post-precursor pulse (413) and the silicon-containing precursor pulse (414) is followed by a post-precursor purge (415), and the plasma pulse (416) is followed by a post-plasma purge (417). The purge time for the post-precursor purges (413, 415) may be between 0.5 to 10 seconds, or between 1 to 5 seconds. The purge time for the post-plasma purge may be between 0 to 10 seconds, or between 0.5 to 5 seconds. Purging can be done, for example, by exposing the substrate to a noble gas or an inert gas or without gas flowing. Exemplary noble gasses include He, Ne, Ar, Xe, and Kr. Exemplary inert gases include N₂. In the embodiment where the purge is done without gas flowing the system is pumped down. Thus, a layer comprising boron carbon nitride is formed on the substrate. When a desired amount of layer comprising boron carbon nitride has been formed on the substrate, the method ends (418). In some embodiments, the resulting layer may have a refractive index of at least 1.4 to at most 2.8, for example at least 1.7 to at most 2.2, such as between 1.75 to 2.0.

Without limit the current disclosure to any specific theory, the layer composition is driven partly by the reaction mechanism, or in other words, the structure and nitrogen-containing ligands present in the silicon-containing precursor. The sole source of carbon is in the silicon-containing precursor. The presence of carbon in the layers indicates, the N—C portion of the silicon-containing precursor remains, at least partly, even after the plasma exposure. Reversely, the Si-Hx portion of the silicon-containing precursor most likely reacts with the —Br left by the BBr₃ and leaves the system as a silicon bromide during the purge step. Therefore, it is plausible the layer composition can be tuned to some extent by modifying the N-containing portion of the silicon-containing precursor, as the Si—N bond is expected to break in the deposition.

Increasing the carbon content in the boron carbon nitride layers can be accomplished by modifying the N-based ligand in the silicon-containing precursor. The possibilities are nearly limitless. Some exemplary embodiments include: heterocyclic ligands (one nitrogen atoms, three or more carbon atoms) to increase carbon-content in the layer, N—C—N heterocycles to incorporate more nitrogen in the layer and heterocycles containing other atoms than just C.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for forming a layer comprising boron, carbon and nitrogen on a substrate, the method comprising:
providing a substrate into a reaction chamber; and
executing a plurality of deposition cycles, a deposition cycle comprising:
providing a boron precursor in vapor phase in the reaction chamber;
providing a silicon-containing precursor in vapor phase in the reaction chamber;
providing a plasma gas in the reaction chamber; and
generating a plasma in the plasma gas;
thereby forming the layer comprising boron, carbon and nitrogen on the substrate.

2. The method according to claim 1, wherein the silicon-containing precursor further comprises carbon and nitrogen.

3. The method according to claim 2, wherein the silicon atom in the silicon-containing precursor is bonded to at least one alkyl group via a nitrogen bridge.

4. The method according to claim 1, wherein the silicon-containing precursor further comprises heterocyclic ligands.

5. The method according to claim 1, wherein the silicon-containing precursor further comprises heterocycles containing other atoms than only carbon.

6. The method according to claim 1, wherein the silicon-containing precursor further comprises N—C—N heterocycles.

7. The method according to claim 1, wherein the boron precursor comprises a boron halide.

8. The method according to claim 7, wherein the boron halide comprises boron bromide.

9. The method according to claim 1, wherein the method further comprises a purge step after providing the boron precursor into the reaction chamber.

10. The method according to claim 1, wherein the method further comprises a purge step after providing the silicon-containing precursor into the reaction chamber.

11. The method according to claim 1, wherein the method further comprises a purge step after providing the plasma into the reaction chamber.

12. The method according to claim 1, wherein the plasma gas comprises at least one of the compounds selected from the group consisting of: ammonia, nitrogen, hydrogen, and a noble gas.

13. The method according to claim 1, wherein the plasma is a direct plasma.

14. The method according to claim 1, wherein the plasma is a remote plasma.

15. A semiconductor processing apparatus comprising:
a reaction chamber comprising a substrate support for supporting a substrate;
a heater constructed and arranged to heat the substrate in the reaction chamber;
a plasma module comprising a radio frequency power source constructed and arranged to generate a plasma;
a plasma gas source in fluid communication with the plasma module;
a boron precursor source in fluid connection with the reaction chamber via one or more precursor valves;
a silicon-containing precursor source in fluid connection with the reaction chamber via one or more precursor valves; and,
a controller operably connected to the plasma module and the one or more precursor valves, and provided with a non-transitory computer readable medium programmed to cause the semiconductor processing apparatus to execute a plurality of deposition cycles, the deposition cycles comprising: providing a boron precursor in vapor phase in the reaction chamber; providing a silicon-containing precursor in vapor phase in the reaction chamber; providing a plasma gas in the reaction chamber; and generating a plasma in the plasma gas.
